(19) United States
(12) Patent Application Publication
(10) Pub. No.: US 2021/0375997 A1
(43) Pub. Date: Dec. 2, 2021

(54) SOLID-STATE IMAGING DEVICE AND MANUFACTURING METHOD, AND ELECTRONIC APPARATUS

(71) Applicant: SONY SEMICONDUCTOR SOLUTIONS CORPORATION, KANAGAWA (JP)

(72) Inventor: YUTA NAKAMURA, KANAGAWA (JP)

(21) Appl. No.: 17/277,044

(22) PCT Filed: Sep. 13, 2019
(86) PCT No.: PCT/JP2019/036034

§ 371 Date: Mar. 17, 2021

(30) Foreign Application Priority Data
Sep. 28, 2018 (JP) 2018-184633

(51) Int. Cl. H01L 27/30; H01L 23/00; H01L 51/00

(52) U.S. Cl. CPC H01L 27/307; H01L 24/08; H01L 24/80; H01L 2224/80896; H01L 2224/08145; H01L 2224/80895; H01L 51/0024

(57) ABSTRACT

The present disclosure relates to a solid-state imaging device and a manufacturing method, and an electronic apparatus that allow the reduction of manufacturing steps to reduce costs. The solid-state imaging device includes a sensor substrate in which a plurality of pixels is formed, and a logic substrate in which at least a logic circuit is formed. Then, the sensor substrate and the logic substrate form a stacked structure by a step of picking out and bonding the sensor substrate that is a non-defective product to a logic wafer in which a plurality of the logic circuits is formed before the logic substrate is separated as an individual piece. The present technology can be applied to, for example, a back-illuminated stacked CMOS image sensor.

### TECHNICAL FIELD

The present disclosure relates to a solid-state imaging device and a manufacturing method, and an electronic apparatus, and more particularly, relates to a solid-state imaging device and a manufacturing method, and an electronic apparatus that allow the reduction of manufacturing steps to reduce costs.

### BACKGROUND ART

Electronic apparatuses having an imaging function such as digital still cameras and digital video cameras have used, for example, a solid-state imaging device such as a charge-coupled device (CCD) or a complementary metal-oxide semiconductor (CMOS) image sensor. Furthermore, in recent years, miniaturization and higher functionality of solid-state imaging devices have been promoted, and stacked CMOS image sensors have been widely adopted.

For example, as a technology for downsizing the configuration of an imaging apparatus, a technology has been proposed which stacks a solid-state imaging device and a circuit such as a signal processing circuit or a memory circuit by wafer-on-wafer (WoW) in which they are bonded in wafer states (see, for example, Patent Document 1).

### CITATION LIST

### Patent Document

Patent Document 1: Japanese Patent Application Laid-Open No. 2014-099582

### SUMMARY OF THE INVENTION

### Problems to be Solved by the Invention

By the way, conventional manufacturing methods have adopted a chip-on-wafer (CoW) process flow in which non-defective chips in a logic substrate are picked out and bonded to a sensor substrate by CoW. Then, after the bonding of the logic substrate to the sensor substrate, a step of performing WoW bonding to a support substrate to thin the sensor substrate, and thinning the sensor substrate has been required. The conventional manufacturing methods thus have many manufacturing steps, and cost high. Their improvements are therefore required.

The present disclosure has been made in view of such circumstances, and is intended to allow the reduction of manufacturing steps to reduce costs.

### Solutions to Problems

A solid-state imaging device according to one aspect of the present disclosure includes a sensor substrate in which a plurality of pixels is formed, and a logic substrate in which at least a logic circuit is formed, in which the sensor substrate and the logic substrate form a stacked structure by a step of picking out and bonding the sensor substrate that is a non-defective product to a logic wafer in which a plurality of the logic circuits is formed before the logic substrate is separated as an individual piece.

A manufacturing method according to one aspect of the present disclosure includes, by a manufacturing apparatus that manufactures a solid-state imaging device including a sensor substrate in which a plurality of pixels is formed, and a logic substrate in which at least a logic circuit is formed, a step of picking out and bonding the sensor substrate that is a non-defective product to a logic wafer in which a plurality of the logic circuits is formed before the logic substrate is separated as an individual piece, whereby the sensor substrate and the logic substrate form a stacked structure.

An electronic apparatus according to one aspect of the present disclosure includes a solid-state imaging device including a sensor substrate in which a plurality of pixels is formed, and a logic substrate in which at least a logic circuit is formed, in which the sensor substrate and the logic substrate form a stacked structure by a step of picking out and bonding the sensor substrate that is a non-defective product to a logic wafer in which a plurality of the logic circuits is formed before the logic substrate is separated as an individual piece.

According to one aspect of the present disclosure, a sensor substrate and a logic substrate form a stacked structure by a step of picking out and bonding the sensor substrate that is a non-defective product to a logic wafer in which a plurality of the logic circuits is formed before the logic substrate is separated as an individual piece.

### BRIEF DESCRIPTION OF DRAWINGS

FIG. 1 is a diagram showing a configuration example of an embodiment of an imaging device to which the present technology is applied.

FIG. 2 is a schematic cross-sectional view of the imaging device.

FIG. 3 is a diagram illustrating a manufacturing method of picking out a sensor substrate and bonding it to a logic wafer.

FIG. 4 is a diagram illustrating a method of manufacturing an imaging device of a first configuration example.

FIG. 5 is a diagram illustrating a method of manufacturing an imaging device of a second configuration example.

FIG. 6 is a diagram illustrating a method of manufacturing an imaging device of a third configuration example.

FIG. 7 is a diagram illustrating a method of manufacturing an imaging device of a fourth configuration example.

FIG. 8 is a diagram illustrating a method of manufacturing an imaging device of a fifth configuration example.

FIG. 9 is a diagram illustrating a method of manufacturing an imaging device of a sixth configuration example.

FIG. 10 is a diagram illustrating the method of manufacturing the imaging device of the sixth configuration example.

FIG. 11 is a diagram illustrating a method of manufacturing an imaging device of a seventh configuration example.

FIG. 12 is a diagram illustrating the method of manufacturing the imaging device of the seventh configuration example.

FIG. 13 is a diagram illustrating a method of manufacturing an imaging device of an eighth configuration example.

FIG. 14 is a block diagram showing a configuration example of an imaging apparatus.

FIG. 15 is a diagram showing usage examples of using an image sensor.

### MODE FOR CARRYING OUT THE INVENTION

Hereinafter, a specific embodiment to which the present technology is applied will be described in detail with reference to the drawings.

<Configuration Example of Imaging Device>

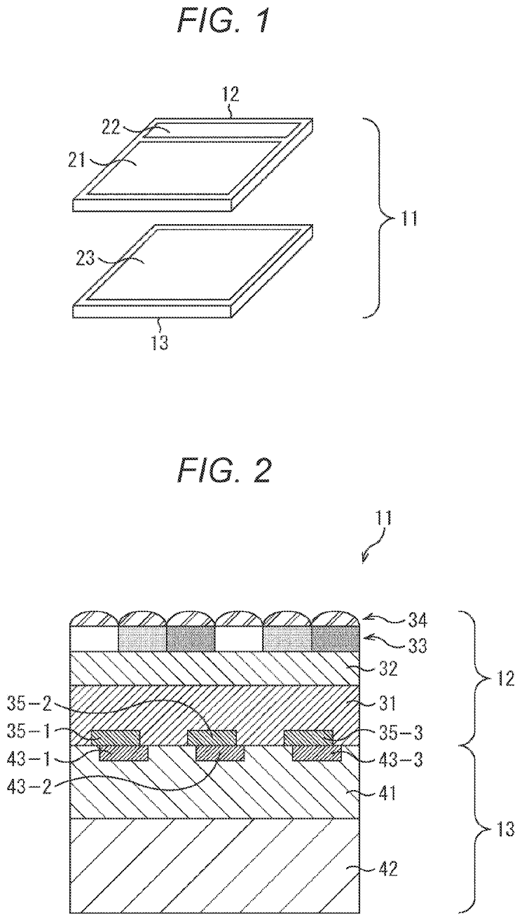

FIG. 1 is a diagram showing a configuration example of an embodiment of an imaging device to which the present technology is applied.

An imaging device 11 shown in FIG. 1 is, for example, a stacked CMOS image sensor including a sensor substrate 12 and a logic substrate 13 stacked in layers. Furthermore, the imaging device 11 is a back-illuminated CMOS image sensor that is illuminated with light from the back opposite to the front when a silicon wafer constituting the sensor substrate 12 is manufactured.

In the sensor substrate 12, a pixel region 21 in which pixels that perform photoelectric conversion are formed in an array, and a control circuit 22 for controlling the drive of a plurality of pixels provided in the pixel region 21 are formed.

In the logic substrate 13, a logic circuit 23 for performing various types of image processing on a pixel signal output from each pixel of the sensor substrate 12 is formed. In addition, a memory circuit for temporarily storing pixel signals may be formed in the logic substrate 13.

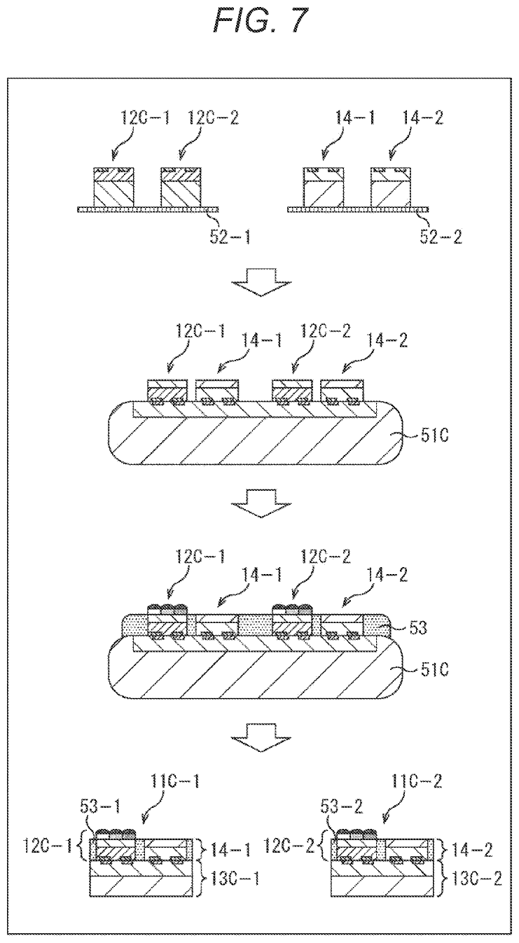

Note that the imaging device 11 may adopt a three-layer structure in which a memory substrate 14 (see FIG. 7) is stacked in addition to the sensor substrate 12 and the logic substrate 13, or a stacked structure including three or more layers of substrates or the like.

FIG. 2 shows a schematic cross-sectional view of the imaging device 11.

As shown in FIG. 2, the sensor substrate 12 includes a wiring layer 31, a semiconductor layer 32, a filter layer 33, and an on-chip lens layer 34 stacked on top of each other. The logic substrate 13 includes a wiring layer 41 and a semiconductor layer 42 stacked on top of each other.

In the wiring layer 31, wiring for transmitting drive signals to drive the pixels, wiring for transmitting pixel signals read from the pixels, etc. are formed. Further, in the wiring layer 31, a plurality of electrode pads 35 (three electrode pads 35-1 to 35-3 in the example of FIG. 2) is formed in a surface bonded to the logic substrate 13.

In the semiconductor layer 32, a photodiode and transistors are formed in each pixel provided in the pixel region 21. Further, in the semiconductor layer 32, transistors constituting the control circuit 22 are formed.

In the filter layer 33, for example, color filters that transmit red, green, and blue light are disposed, one for each pixel provided in the pixel region 21.

In the on-chip lens layer 34, a small lens for condensing light onto the photodiode is disposed for each pixel provided in the pixel region 21.

In the wiring layer 41, wiring for transmitting pixel signals read from the sensor substrate 12 to the logic circuit 23, wiring for transmitting control signals provided from the outside to the control circuit 22 of the sensor substrate 12, etc. are formed. Further, in the wiring layer 41, a plurality of electrode pads 43 (three electrode pads 43-1 to 43-3 in the example of FIG. 2) is formed in a surface bonded to the sensor substrate 12.

In the semiconductor layer 42, transistors constituting the logic circuit 23 are formed.

Thus, in the imaging device 11 of the stacked structure in which the sensor substrate 12 and the logic substrate 13 are stacked in layers, the plurality of electrode pads 35 in the wiring layer 31 on the sensor substrate 12 side and the plurality of electrode pads 43 in the wiring layer 41 on the logic substrate 13 side are mechanically and electrically bonded (for example, Cu—Cu bonded).

Then, the imaging device 11 of the present embodiment is manufactured by a manufacturing method including a step of picking out and bonding the sensor substrate 12 to a wafer in which the logic substrate 13 is formed through a CoW process flow, whereby the sensor substrate 12 and the logic substrate 13 form a stacked structure.

For example, in the method of manufacturing the imaging device 11, the pixel region 21 and the control circuit 22 are formed in each region to be cut out as the sensor substrate 12 in one silicon wafer, and the silicon wafer is diced to cut out individual sensor substrates 12.

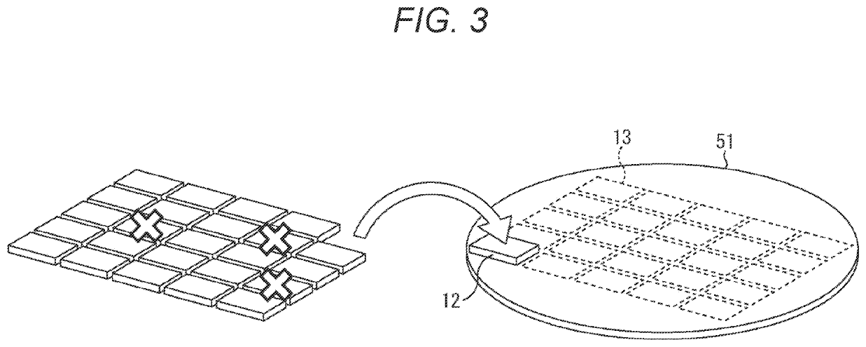

Then, as shown in FIG. 3, a known good die (KGD) is selected from those sensor substrates 12, that is, only a non-defective sensor substrate 12 is picked out. Subsequently, the sensor substrate 12 is CoW-bonded to a region where the logic substrate 13 is formed in a logic wafer 51 (at this point of time, in a state where the logic circuit 23 is formed before the logic substrate 13 is separated as an individual piece). At this time, defective sensor substrates 12 (x marks in the figure) are not picked out.

After that, as will be described later, thinning, customization, etc. are performed on the sensor substrates 12 in a state of being stacked on the logic wafer 51, and the logic wafer 51 is diced to separate imaging devices 11 into individual pieces.

<Method of Manufacturing Imaging Device of First Configuration Example>

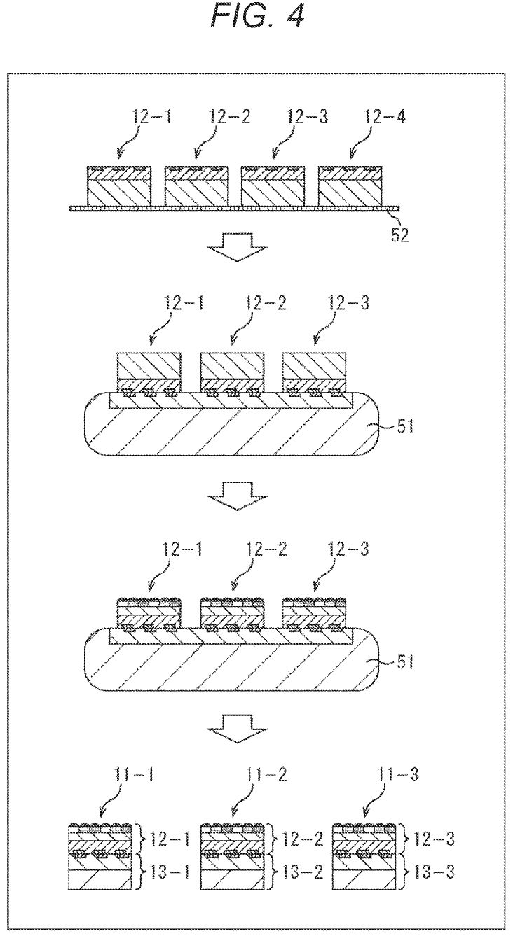

With reference to FIG. 4, a method of manufacturing an imaging device of a first configuration example will be described.

In a first step, a wiring layer 31 for each sensor substrate 12 is formed on the surface of a silicon wafer, and the silicon wafer is diced on a dicing tape 52. As a result, as shown in the first stage from the top of FIG. 4, a plurality of sensor substrates 12 (at this point of time, in a state where photodiodes are formed in semiconductor layers 32, processing to form transistors etc. is performed on the front side, and no processing is performed on the back side) is separated into individual pieces.

In a second step, KGDs are selected from among the plurality of sensor substrates 12, and in a logic wafer 51 in which a plurality of logic circuits 23 constituting logic substrates 13 is formed, KGDs of the logic circuits 23 are selected. Then, as described with reference to FIG. 3, the non-defective sensor substrates 12 are picked out, and the sensor substrates 12 are CoW-bonded onto the non-defective logic circuits 23 with high accuracy. As a result, as shown in the second stage from the top of FIG. 4, the plurality of sensor substrates 12 is stacked on the logic wafer 51 before the logic substrates 13 are separated into individual pieces.

In a third step, as shown in the third stage from the top of FIG. 4, the semiconductor layers 32 of the sensor substrates 12 are thinned, and processing to customize the sensor substrates 12 is performed. For example, the semiconductor layers 32 are thinned by various types of processing to reduce film thickness, such as a grinder or chemical mechanical polishing (CMP), to expose photodiode layers in the semiconductor layers 32. After that, filter layers 33 and on-chip lens layers 34 are stacked on the back of the semiconductor layers 32.

In a fourth step, the logic wafer 51 is diced, so that, as shown in the fourth stage from the top of FIG. 4, imaging devices 11 are manufactured in each of which the sensor substrate 12 and the logic substrate 13 are stacked in layers.

By the manufacturing method as described above, a manufacturing apparatus can manufacture the imaging device 11 of the first configuration example in which the sensor substrate 12 and the logic substrate 13 form a stacked structure.

Further, this manufacturing method eliminates the need for a step of performing WoW bonding to a support substrate to thin the sensor substrates 12, and can reduce manufacturing steps as compared with conventional ones. Specifically, it has been required to perform bonding two times, a step of CoW-bonding a logic substrate to a sensor substrate, and WoW bonding to a support substrate to thin the sensor substrate. By contrast, the method of manufacturing the imaging device 11 only requires CoW-bonding of the sensor substrate 12 to the logic substrate 13. As a result, the imaging device 11 can be manufactured at low costs.

Further, the manufacturing method is more effective than conventional manufacturing methods in that final yields can be enhanced by selecting KGDs because the sensor substrates 12 generally have lower yields than the logic substrates 13. In particular, when the imaging device 11 has a large size such as a one inch or 35 mm full size, more cost advantage can be obtained.

<Method of Manufacturing Imaging Device of Second Configuration Example>

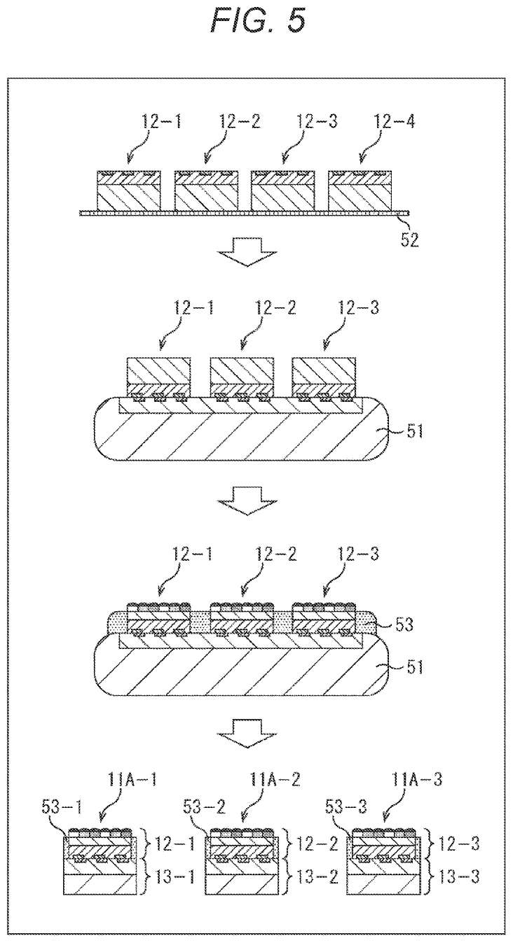

With reference to FIG. 5, a method of manufacturing an imaging device of a second configuration example will be described.

In an eleventh step, processing similar to that in the first step of FIG. 4 is performed, and a plurality of sensor substrates 12 is separated into individual pieces on a dicing tape 52 as shown in the first stage from the top of FIG. 5.

In a twelfth step, processing similar to that in the second step of FIG. 4 is performed, and the plurality of sensor substrates 12 is stacked on a logic wafer 51 as shown in the second stage from the top of FIG. 5.

In a thirteenth step, semiconductor layers 32 of the sensor substrates 12 are thinned, and then, for example, an oxide film 53 is formed to planarize the surfaces of the sensor substrates 12. The planarization with the oxide film 53 like this can eliminate steps produced between the sensor substrates 12. After that, with the surfaces planarized, processing to customize the sensor substrates 12 is performed, and filter layers 33 and on-chip lens layers 34 are stacked as shown in the third stage from the top of FIG. 5. Note that after the steps between the sensor substrates 12 are filled with the oxide film 53, inversion processing that is etching applied to protruding portions at the steps may be performed to facilitate planarization.

In a fourteenth step, the logic wafer 51 is diced. At this time, by using a dicing blade whose width is narrower than the distance between the sensor substrates 12 adjacent to each other, imaging devices 11A of a structure in which the oxide film 53 remains on the sides of the sensor substrates 12 are manufactured as shown in the fourth stage from the top of FIG. 5.

By the manufacturing method as described above, a manufacturing apparatus can manufacture the imaging device 11A of the second configuration example in which the sensor substrate 12 and the logic substrate 13 form a stacked structure, and the sides of the sensor substrate 12 are fixed by the oxide film 53. Then, as described above with reference to FIG. 4, the imaging device 11A allows the reduction of manufacturing steps to reduce costs as compared with conventional ones.

Note that the processing to fill the steps between the sensor substrates 12 with the oxide film 53 may be performed, for example, before the thinning or in the middle of a plurality of thinning steps, instead of only after the semiconductor layers 32 of the sensor substrates 12 are thinned. Furthermore, other than forming the oxide film 53, for example, a desired film other than the oxide film 53 may be formed, or resin may be applied to form a resin film, or another filling material may be used for planarization.

<Method of Manufacturing Imaging Device of Third Configuration Example>

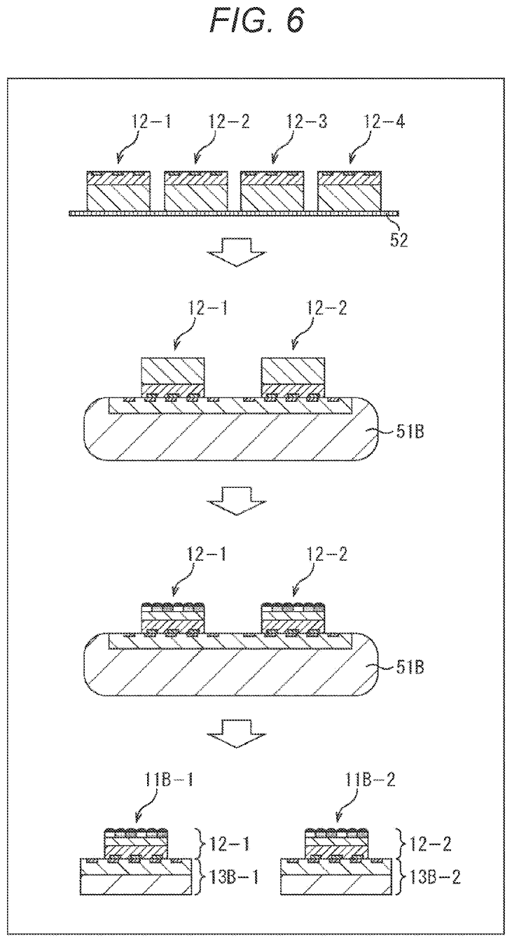

With reference to FIG. 6, a method of manufacturing an imaging device of a third configuration example will be described.

In a twenty-first step, processing similar to that in the first step of FIG. 4 is performed, and a plurality of sensor substrates 12 is separated into individual pieces on a dicing tape 52 as shown in the first stage from the top of FIG. 6.

In a twenty-second step, as in the second step of FIG. 4, non-defective sensor substrates 12 are picked out, and the sensor substrates 12 are CoW-bonded onto non-defective logic circuits 23 with high accuracy. At this time, for example, in a logic wafer 51B, logic circuits 23 larger than those in the logic wafer 51 of FIG. 4 are formed. As shown in the second stage from the top of FIG. 6, the adjacent sensor substrates 12 are widely spaced apart from each other in a one-to-one correspondence with the logic circuits 23.

In a twenty-third step, processing similar to that in the third step of FIG. 4 is performed. As shown in the third stage from the top of FIG. 6, the sensor substrates 12 are thinned and processed to be customized.

In a twenty-fourth step, as in the fourth step of FIG. 4, the logic wafer 51B is diced. At this time, logic substrates 13B have a larger chip size than the logic substrates 13 in FIG. 4. As shown in the fourth stage from the top of FIG. 6, the sensor substrates 12 are relatively smaller than the logic substrates 13B.

By the manufacturing method as described above, a manufacturing apparatus can manufacture an imaging device 11B of the third configuration example in which the sensor substrate 12 and the logic substrate 13B form a stacked structure, and the sensor substrate 12 has a smaller chip size than the logic substrate 13B. Then, as described above with reference to FIG. 4, the imaging device 11B allows the reduction of manufacturing steps to reduce costs as compared with conventional ones.

<Method of Manufacturing Imaging Device of Fourth Configuration Example>

With reference to FIG. 7, a method of manufacturing an imaging device of a fourth configuration example will be described.

In a thirty-first step, processing similar to that in the first step of FIG. 4 is performed, and a plurality of sensor substrates 12C is separated into individual pieces on a dicing tape 52-1 as shown in the first stage from the top of FIG. 7. Further, in parallel, a plurality of memory substrates 14 is separated into individual pieces on a dicing tape 52-2. In each memory substrate 14, for example, a memory device for storing pixel signals is formed.

In a thirty-second step, processing similar to that in the second step of FIG. 4 is performed, and as shown in the second stage from the top of FIG. 7, the plurality of sensor substrates 12 is stacked on a logic wafer 51C, and the plurality of memory substrates 14 is stacked on the logic wafer 51C.

In a thirty-third step, processing similar to that in the thirteenth step of FIG. 5 is performed, and an oxide film 53 is formed to planarize the surfaces of the sensor substrates 12C and the memory substrates 14.

In a thirty-fourth step, processing similar to that in the fourteenth step of FIG. 5 is performed, and as shown in the fourth stage from the top of FIG. 7, the logic wafer 51C is diced such that the sensor substrates 12C are relatively smaller than logic substrates 13C.

By the manufacturing method as described above, a manufacturing apparatus can manufacture an imaging device 11C of the fourth configuration example in which the sensor substrate 12C and the memory substrate 14, and the logic substrate 13C form a stacked structure, and the sensor substrate 12C is smaller than the logic substrate 13C. Then, as described above with reference to FIG. 4, the imaging device 11C allows the reduction of manufacturing steps to reduce costs as compared with conventional ones.

Note that although each imaging device 11C shown in FIG. 7 has a stacked structure in which the sensor substrate 12C and the memory substrate 14 are stacked on one logic substrate 13C, each may have, for example, a stacked structure in which two sensor substrates 12C are stacked on one logic substrate 13C. Alternatively, in addition to the sensor substrate 12C and the memory substrate 14, a substrate having another function may be stacked on one logic substrate 13C. That is, each imaging device 11C can have a stacked structure in which a plurality of substrates including the sensor substrate 12C is stacked on one logic substrate 13C.

<Method of Manufacturing Imaging Device of Fifth Configuration Example>

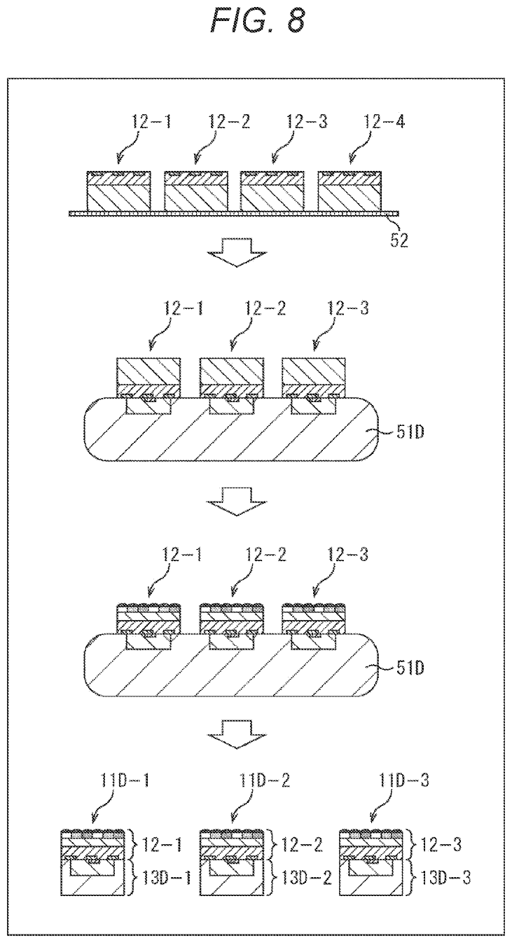

With reference to FIG. 8, a method of manufacturing an imaging device of a fifth configuration example will be described.

In a forty-first step, processing similar to that in the first step of FIG. 4 is performed, and a plurality of sensor substrates 12 is separated into individual pieces on a dicing tape 52 as shown in the first stage from the top of FIG. 8.

In a forty-second step, as in the second step of FIG. 4, non-defective sensor substrates 12 are picked out, and the sensor substrates 12 are CoW-bonded onto non-defective logic circuits 23 with high accuracy. At this time, for example, as shown in the second stage from the top of FIG. 8, logic circuits 23 smaller than those in the logic wafer 51 of FIG. 4 are formed in a logic wafer 51D.

In a forty-third step, processing similar to that in the third step of FIG. 4 is performed, and as shown in the third stage from the top of FIG. 8, the sensor substrates 12 are thinned and processed to be customized.

In a forty-fourth step, as in the fourth step of FIG. 4, the logic wafer 51D is diced. At this time, each logic substrate 13D has a substantial chip size (the size of a region where the logic circuit 23 is formed to provide a function as the logic substrate 13) smaller than that of each logic substrate 13 in FIG. 4. As shown in the fourth stage from the top of FIG. 8, the sensor substrates 12 are relatively smaller than the logic substrates 13D.

By the manufacturing method as described above, a manufacturing apparatus can manufacture an imaging device 11D of the fifth configuration example in which the sensor substrate 12 and the logic substrate 13D form a stacked structure, and the sensor substrate 12 has a substantial chip size larger than that of the logic substrate 13D, that is, the logic substrate 13D has a substantial chip size smaller than that of the sensor substrate 12. Then, as described above with reference to FIG. 4, the imaging device 11D allows the reduction of manufacturing steps to reduce costs as compared with conventional ones.

<Method of Manufacturing Imaging Device of Sixth Configuration Example>

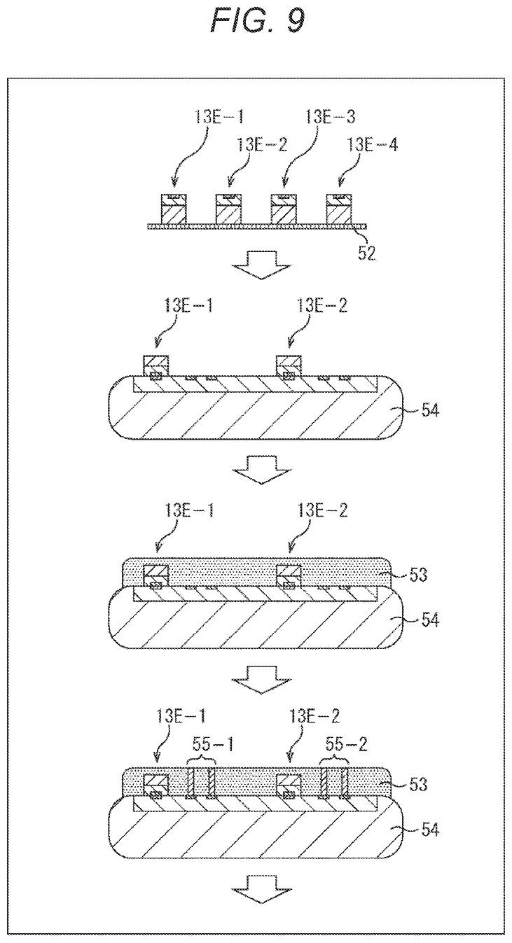

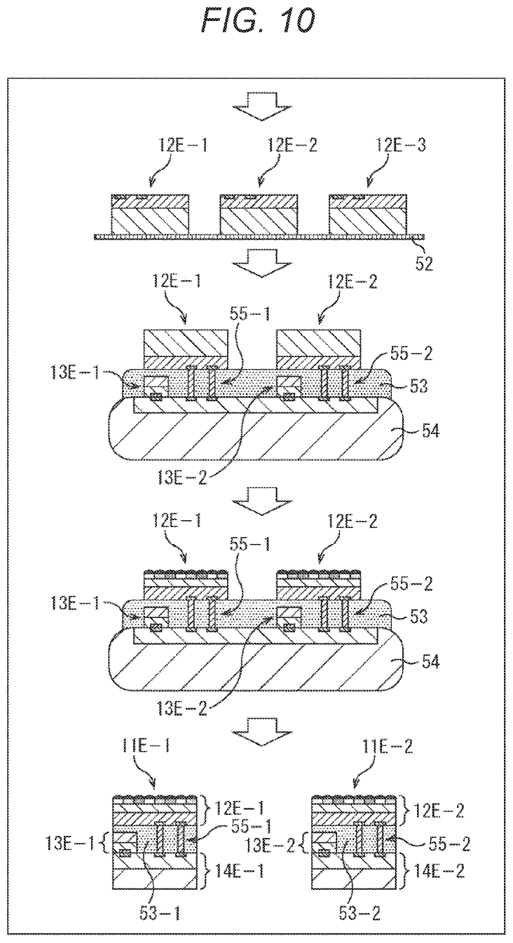

With reference to FIGS. 9 and 10, a method of manufacturing an imaging device of a sixth configuration example will be described.

In a fifty-first step, a logic circuit 23 and a wiring layer 41 for each logic substrate 13E are formed on the surface of a silicon wafer, and the silicon wafer is diced on a dicing tape 52. As a result, as shown in the first stage from the top of FIG. 9, a plurality of logic substrates 13E is separated into individual pieces.

In a fifty-second step, KGDs are selected from among the plurality of logic substrates 13E, and in a memory wafer 54 in which a plurality of memory circuits constituting memory substrates 14E is formed, KGDs of the memory circuits are selected. Then, as described with reference to FIG. 3, the non-defective logic substrates 13E are picked out, and the logic substrates 13E are CoW-bonded onto the non-defective memory circuits with high accuracy. As a result, as shown in the second stage from the top of FIG. 9, the plurality of logic substrates 13E is stacked on the memory wafer 54 before the memory substrates 14E are separated into individual pieces.

In a fifty-third step, as shown in the third stage from the top of FIG. 9, an oxide film 53 is formed to a thickness just enough to hide the memory substrates 14E.

In a fifty-fourth step, as shown in the fourth stage from the top of FIG. 9, through-silicon vias (TSVs) are formed through the oxide film 53, forming through electrodes 55 including a metallic material, which are connected to electrodes formed in the memory circuits in the memory wafer 54.

In a fifty-fifth step, processing similar to that in the first step of FIG. 4 is performed, and a plurality of sensor substrates 12E is separated into individual pieces on a dicing tape 52 as shown in the first stage from the top of FIG. 10.

In a fifty-sixth step, KGDs are selected from among the plurality of sensor substrates 12E to pick out non-defective sensor substrates 12E, and the sensor substrates 12E are electrically connected to non-defective memory circuits via the through electrodes 55. As a result, as shown in the second stage from the top of FIG. 10, the plurality of sensor substrates 12E is stacked via the oxide film 53 on the memory wafer 54 before the memory substrates 14E are separated into individual pieces.

In a fifty-seventh step, processing similar to that in the third step of FIG. 4 is performed, and as shown in the third stage from the top of FIG. 10, the sensor substrates 12E are thinned and processed to be customized.

In a fifty-eighth step, as in the fourth step of FIG. 4, the memory wafer 54 is diced, so that, as shown in the fourth stage from the top of FIG. 10, imaging devices 11E are manufactured in each of which the sensor substrate 12E, the logic substrate 13E, and the memory substrate 14E are stacked in layers.

By the manufacturing method as described above, a manufacturing apparatus can manufacture the imaging device 11E of the sixth configuration example having a three-layer structure in which the sensor substrate 12E, the logic substrate 13E, and the memory substrate 14E are stacked in layers. Then, as described above with reference to FIG. 4, the imaging device 11E allows the reduction of manufacturing steps to reduce costs as compared with conventional ones.

<Method of Manufacturing Imaging Device of Seventh Configuration Example>

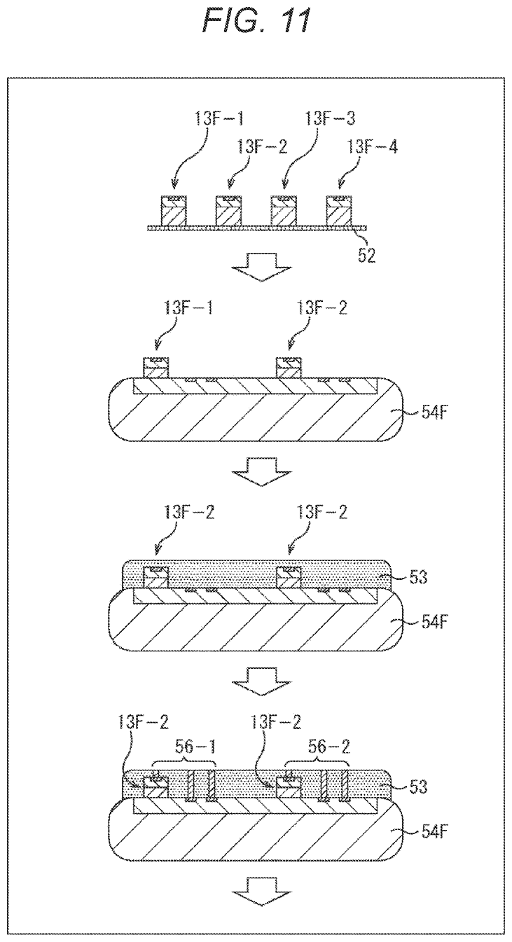

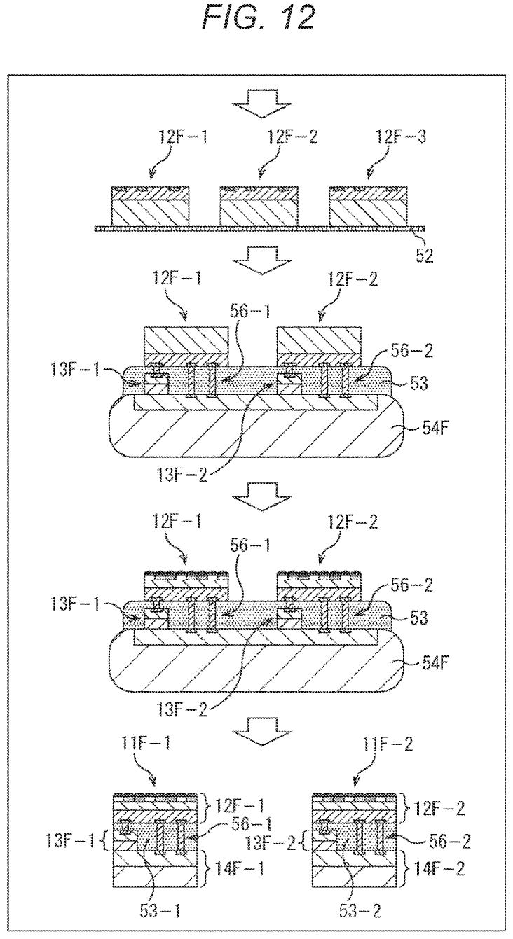

With reference to FIGS. 11 and 12, a method of manufacturing an imaging device of a seventh configuration example will be described.

In a sixty-first step, processing similar to that in the fifty-first step of FIG. 9 is performed, and a plurality of logic substrates 13F is separated into individual pieces on a dicing tape 52 as shown in the first stage from the top of FIG. 11.

In a sixty-second step, processing similar to that in the fifty-second step of FIG. 9 is performed, and a plurality of logic substrates 13F is stacked on a memory wafer 54F before memory substrates 14F are separated into individual pieces. At this time, the plurality of logic substrates 13F is stacked on the memory wafer 54F in an inverted orientation, that is, such that wiring layers 41 face the opposite side to the memory wafer 54F.

In a sixty-third step, as shown in the third stage from the top of FIG. 11, an oxide film 53 is formed to a thickness just enough to hide the memory substrates 14F.

In a sixty-fourth step, as shown in the fourth stage from the top of FIG. 11, through electrodes 56 are formed through the oxide film 53 and connected to electrodes formed in memory circuits of the memory wafer 54F, and electrode pads 43 formed in the wiring layers 41 of the logic substrates 13F.

In a sixty-fifth step, processing similar to that in the first step of FIG. 4 is performed, and a plurality of sensor substrates 12F is separated into individual pieces on a dicing tape 52 as shown in the first stage from the top of FIG. 12.

In a sixty-sixth step, KGDs are selected from among the plurality of sensor substrates 12F to pick out non-defective sensor substrates 12F, and the sensor substrates 12F are electrically connected to non-defective memory circuits via the through electrodes 56. At the same time, the sensor substrates 12F are electrically connected to the logic substrates 13F via the through electrodes 56. As a result, as shown in the second stage from the top of FIG. 12, the plurality of sensor substrates 12F is stacked via the oxide film 53 on the memory wafer 54F before the memory substrates 14F are separated into individual pieces.

In a sixty-seventh step, processing similar to that in the third step of FIG. 4 is performed, and as shown in the third stage from the top of FIG. 12, the sensor substrates 12F are thinned and processed to be customized.

In a sixty-eighth step, as in the fourth step of FIG. 4, the memory wafer 54F is diced, so that, as shown in the fourth stage from the top of FIG. 12, imaging devices 11F are manufactured in each of which the sensor substrate 12F, the logic substrate 13F, and the memory substrate 14F are stacked in layers.

By the manufacturing method as described above, a manufacturing apparatus can manufacture the imaging device 11F of the seventh configuration example having a three-layer structure in which the sensor substrate 12F, the logic substrate 13F, and the memory substrate 14F are stacked in layers. Then, as described above with reference to FIG. 4, the imaging device 11F allows the reduction of manufacturing steps to reduce costs as compared with conventional ones.

Here, in the imaging device 11F, the logic substrate 13F and the sensor substrate 12F form a stacked structure with the wiring layer 41 of the logic substrate 13F facing the sensor substrate 12F. On the other hand, in the imaging device 11E of FIG. 10, the logic substrate 13E and the sensor substrate 12E form a stacked structure with the wiring layer 41 of the logic substrate 13E facing the memory substrate 14E, that is, facing the opposite side to the sensor substrate 12F. That is, another substrate forming a stacked structure with the sensor substrate (for example, the logic substrate 13, the memory substrate 14, or the like) may face either upward or downward with respect to the sensor substrate 12.

<Method of Manufacturing Imaging Device of Eighth Configuration Example>

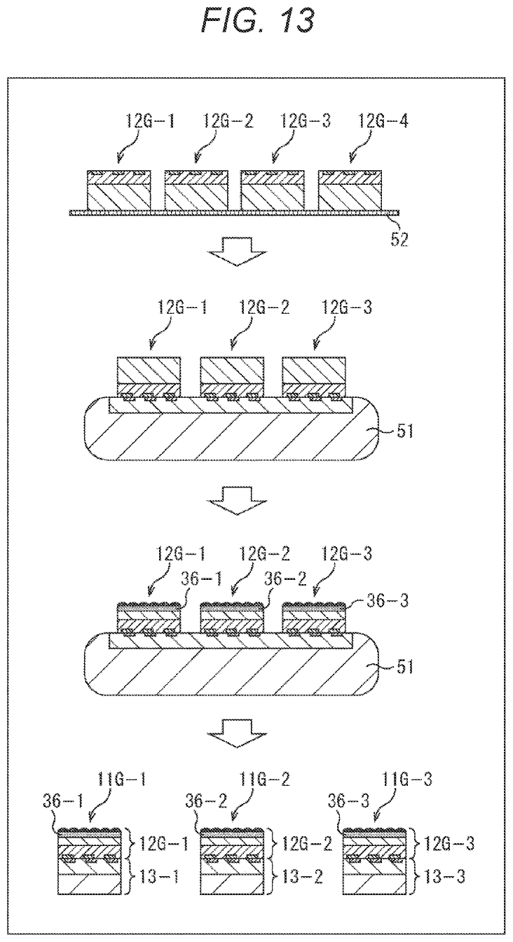

With reference to FIG. 13, a method of manufacturing an imaging device of an eighth configuration example will be described.

In a seventy-first step, processing similar to that in the first step of FIG. 4 is performed, and a plurality of sensor substrates 12G is separated into individual pieces on a dicing tape 52 as shown in the first stage from the top of FIG. 13.

In a seventy-second step, processing similar to that in the second step of FIG. 4 is performed, and a plurality of sensor substrates 12G is stacked on a logic wafer 51 as shown in the second stage from the top of FIG. 13.

In a seventy-third step, processing similar to that in the third step of FIG. 4 is performed, and as shown in the third stage from the top of FIG. 13, the sensor substrates 12G are thinned and processed to be customized. At this time, instead of filter layers 33 (see FIG. 2), organic photoelectric conversion films 36 made from an organic material are formed which receive light and convert it into electric charge.

In a seventy-fourth step, as in the fourth step of FIG. 4, the logic wafer 51 is diced, so that, as shown in the fourth stage from the top of FIG. 13, imaging devices 11G are manufactured in each of which the sensor substrate 12G and the logic substrate 13 are stacked in layers.

By the manufacturing method as described above, a manufacturing apparatus can manufacture the imaging device 11G of the eighth configuration example in which the sensor substrate 12G including the organic photoelectric conversion film 36 and the logic substrate 13 form a stacked structure. Then, as described above with reference to FIG. 4, the imaging device 11G allows the reduction of manufacturing steps to reduce costs as compared with conventional ones.

<Configuration Example of Electronic Apparatus>

The imaging device 11 as described above can be applied, for example, to various types of electronic apparatuses including imaging systems such as digital still cameras and digital video cameras, mobile phones with an imaging function, and other apparatuses with an imaging function.

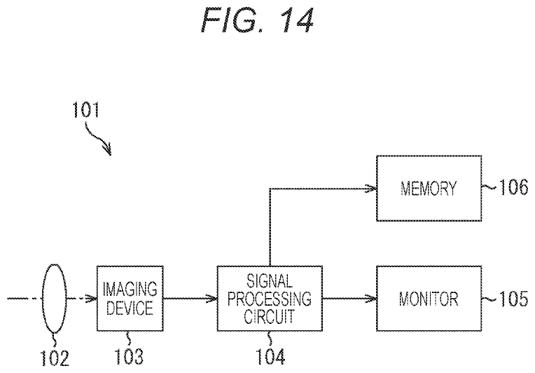

FIG. 14 is a block diagram showing a configuration example of an imaging apparatus mounted on an electronic apparatus.

As shown in FIG. 14, an imaging apparatus 101 includes an optical system 102, an imaging device 103, a signal processing circuit 104, a monitor 105, and memory 106, and can capture still images and moving images.

The optical system 102 includes one or a plurality of lenses, and guides image light (incident light) from a subject to the imaging device 103, forming an image on a light-receiving surface (sensor portion) of the imaging device 103.

As the imaging device 103, the imaging device 11 described above is applied. Electrons are accumulated in the imaging device 103 for a certain period or time according to an image formed on the light-receiving surface via the optical system 102. Then, signals corresponding to the electrons accumulated in the imaging device 103 are provided to the signal processing circuit 104.

The signal processing circuit 104 performs various types of signal processing on pixel signals output from the imaging device 103. An image (image data) obtained by the signal processing circuit 104 performing the signal processing is provided to the monitor 105 to be displayed, or provided to the memory 106 to be stored (recorded).

The imaging apparatus 101 configured like this can achieve, for example, a lower price by the application of the above-described imaging device 11.

<Examples of Use of Image Sensor>

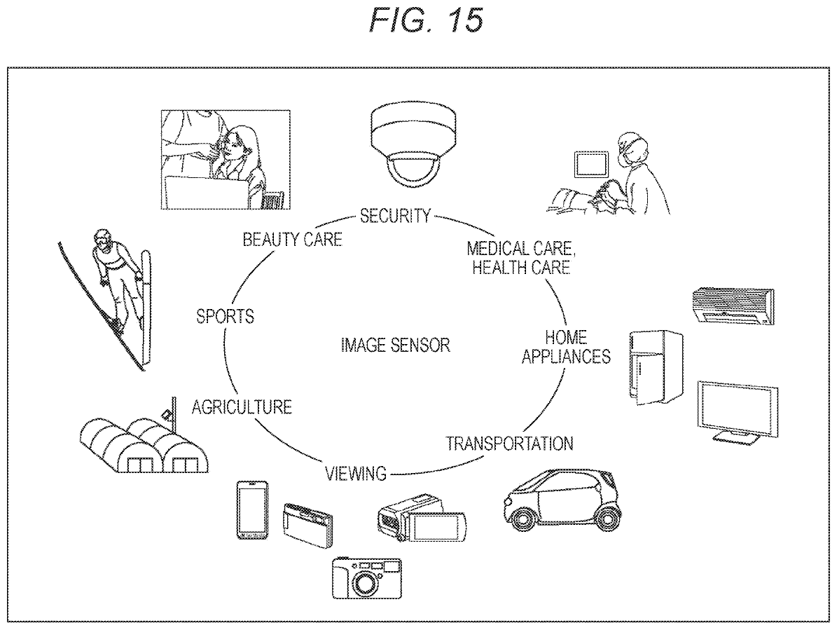

FIG. 15 is a diagram showing usage examples of using the above-described image sensor (imaging device).

The above-described image sensor can be used, for example, in various cases where light such as visible light, infrared light, ultraviolet light, or X-rays are sensed as described below.
Apparatuses for capturing images for viewing use, such as digital cameras and portable devices with a camera function
Apparatuses for transportation use, such as on-board sensors for imaging the front, back, surroundings, interior, etc. of an automobile, surveillance cameras for monitoring running vehicles and roads, and distance measurement sensors for measuring distance between vehicles or the like, for safe driving such as automatic stopping, recognition of a driver's conditions, and the like
Apparatuses used in home appliances such as TVs, refrigerators, and air conditioners, for imaging a user gesture and performing a device operation in accordance with the gesture
Apparatuses for medical care and health care use, such as endoscopes and apparatuses that perform angiography through reception of infrared light
Apparatuses for security use, such as surveillance cameras used for crime prevention and cameras used for person authentication
Apparatuses for beauty care use, such as skin measuring instruments for imaging skin and microscopes for imaging the scalp
Apparatuses for sports use, such as action cameras and wearable cameras for sports applications and the like
Apparatuses for agricultural use, such as cameras for monitoring the conditions of fields or crops

<Examples of Configuration Combinations>

Note that the present technology can also have the following configurations.

(1)

A solid-state imaging device including:

a sensor substrate in which a plurality of pixels is formed; and

a logic substrate in which at least a logic circuit is formed,

in which the sensor substrate and the logic substrate form a stacked structure by a step of picking out and bonding the sensor substrate that is a non-defective product to a logic wafer in which a plurality of the logic circuits is formed before the logic substrate is separated as an individual piece.

(2)

The solid-state imaging device according to (1) above, in which

a plurality of substrates including the sensor substrate is stacked on the logic substrate, forming a stacked structure.

(3)

The solid-state imaging device according to (2) above, in which

the sensor substrate and a memory substrate in which a memory circuit that stores pixel signals is formed are stacked on the logic substrate, forming a stacked structure.

(4)

The solid-state imaging device according to (3) above, in which

another substrate is stacked on the sensor substrate with a wiring layer facing the sensor substrate, forming a stacked structure.

(5)

The solid-state imaging device according to (3) above, in which

another substrate is stacked on the sensor substrate with a wiring layer facing an opposite side to the sensor substrate, forming a stacked structure.

(6)

The solid-state imaging device according to any one of (1) to (5) above, in which

the sensor substrate is formed by bonding a plurality of the sensor substrates to the logic wafer, and performing processing to customize the sensor substrate with a planarizing film formed to fill steps between the plurality of sensor substrates for planarization.

(7)

The solid-state imaging device according to (6) above, in which

inversion processing is performed on protruding portions at the steps between the plurality of sensor substrates after the steps are filled with the planarizing film.

(8)

The solid-state imaging device according to any one of (1) to (7) above, in which

electrode pads disposed in respective bonding surfaces of the sensor substrate and the logic wafer are electrically bonded to each other when the sensor substrate is bonded to the logic wafer.

(9)

The solid-state imaging device according to any one of (1) to (8) above, in which

the sensor substrate and the logic substrate are electrically bonded via a through electrode extending through an oxide film provided between the sensor substrate and the logic substrate.

(10)

The solid-state imaging device according to any one of (1) to (9) above, in which

the sensor substrate includes an organic photoelectric conversion film made from an organic material which receives light and converts the light into electric charge.

(11)

The solid-state imaging device according to any one of (1) to (10) above, in which

the sensor substrate has a relatively smaller chip size than the logic substrate.

(12)

The solid-state imaging device according to any one of (1) to (10) above, in which

the logic substrate has a relatively smaller chip size than the sensor substrate.

(13)

A manufacturing method including:

by a manufacturing apparatus that manufactures a solid-state imaging device including a sensor substrate in which a plurality of pixels is formed, and a logic substrate in which at least a logic circuit is formed,

a step of picking out and bonding the sensor substrate that is a non-defective product to a logic wafer in which a plurality of the logic circuits is formed before the logic substrate is separated as an individual piece, whereby the sensor substrate and the logic substrate form a stacked structure.

(14)

An electronic apparatus including a solid-state imaging device including

a sensor substrate in which a plurality of pixels is formed, and

a logic substrate in which at least a logic circuit is formed,

in which the sensor substrate and the logic substrate form a stacked structure by a step of picking out and bonding the sensor substrate that is a non-defective product to a logic wafer in which a plurality of the logic circuits is formed before the logic substrate is separated as an individual piece.

Note that the present embodiment is not limited to the above-described embodiment, and various changes can be made without departing from the scope of the present disclosure. Furthermore, the effects described in the present description are merely examples and non-limiting, and other effects may be included.

### REFERENCE SIGNS LIST

11 Imaging device
12 Sensor substrate
13 Logic substrate
14 Memory substrate
21 Pixel region
22 Control circuit
23 Logic circuit
31 Wiring layer
32 Semiconductor layer
33 Filter layer
34 On-chip lens layer
35 Electrode pad
36 Organic photoelectric conversion film
41 Wiring layer
42 Semiconductor layer
43 Electrode pad
51 Logic wafer
52 Dicing tape
53 Oxide film
54 Memory wafer
55 Through electrode

1. A solid-state imaging device comprising:
a sensor substrate in which a plurality of pixels is formed; and
a logic substrate in which at least a logic circuit is formed,
wherein the sensor substrate and the logic substrate form a stacked structure by a step of picking out and bonding the sensor substrate that is a non-defective product to a logic wafer in which a plurality of the logic circuits is formed before the logic substrate is separated as an individual piece.

2. The solid-state imaging device according to claim 1, wherein
a plurality of substrates including the sensor substrate is stacked on the logic substrate, forming a stacked structure.

3. The solid-state imaging device according to claim 2, wherein
the sensor substrate and a memory substrate in which a memory circuit that stores pixel signals is formed are stacked on the logic substrate, forming a stacked structure.

4. The solid-state imaging device according to claim 3, wherein
another substrate is stacked on the sensor substrate with a wiring layer facing the sensor substrate, forming a stacked structure.

5. The solid-state imaging device according to claim 3, wherein
another substrate is stacked on the sensor substrate with a wiring layer facing an opposite side to the sensor substrate, forming a stacked structure.

6. The solid-state imaging device according to claim 1, wherein
the sensor substrate is formed by bonding a plurality of the sensor substrates to the logic wafer, and performing processing to customize the sensor substrate with a planarizing film formed to fill steps between the plurality of sensor substrates for planarization.

7. The solid-state imaging device according to claim 6, wherein
inversion processing is performed on protruding portions at the steps between the plurality of sensor substrates after the steps are filled with the planarizing film.

8. The solid-state imaging device according to claim 1, wherein
electrode pads disposed in respective bonding surfaces of the sensor substrate and the logic wafer are electrically bonded to each other when the sensor substrate is bonded to the logic wafer.

9. The solid-state imaging device according to claim 1, wherein
the sensor substrate and the logic substrate are electrically bonded via a through electrode extending through an oxide film provided between the sensor substrate and the logic substrate.

10. The solid-state imaging device according to claim 1, wherein
the sensor substrate includes an organic photoelectric conversion film made from an organic material which receives light and converts the light into electric charge.

11. The solid-state imaging device according to claim 1, wherein
the sensor substrate has a relatively smaller chip size than the logic substrate.

12. The solid-state imaging device according to claim 1, wherein
the logic substrate has a relatively smaller chip size than the sensor substrate.

13. A manufacturing method comprising:
by a manufacturing apparatus that manufactures a solid-state imaging device comprising a sensor substrate in which a plurality of pixels is formed, and a logic substrate in which at least a logic circuit is formed,
a step of picking out and bonding the sensor substrate that is a non-defective product to a logic wafer in which a plurality of the logic circuits is formed before the logic substrate is separated as an individual piece, whereby the sensor substrate and the logic substrate form a stacked structure.

14. An electronic apparatus comprising a solid-state imaging device including
a sensor substrate in which a plurality of pixels is formed, and
a logic substrate in which at least a logic circuit is formed,
wherein the sensor substrate and the logic substrate form a stacked structure by a step of picking out and bonding the sensor substrate that is a non-defective product to a logic wafer in which a plurality of the logic circuits is formed before the logic substrate is separated as an individual piece.
